(19) United States
(12) Patent Application Publication
(10) Pub. No.: US 2020/0203197 A1
(43) Pub. Date: Jun. 25, 2020

(54) MULTI-STATION PROCESSING CHAMBER FOR SEMICONDUCTOR

(71) Applicant: PIOTECH CO., LTD., Shenyang (CN)

(72) Inventors: HUAQIANG TAN, Shenyang (CN); REN ZHOU, Shenyang (CN); ZHUO WANG, Shenyang (CN); DEZAN YANG, Shenyang (CN); GIYOUL KIM, Shenyang (CN); JING LI, Shenyang (CN); JUNICHI ARAMI, Shenyang (CN); ZHONGWU LIU, Shenyang (CN); SI SHEN, Shenyang (CN); BRIAN LU, Shenyang (CN); SEAN CHANG, Shenyang (CN); GREGORY SIU, Shenyang (CN)

(21) Appl. No.: 16/711,942

(22) Filed: Dec. 12, 2019

(30) Foreign Application Priority Data
Dec. 24, 2018 (CN) 201811581220.2

(51) Int. Cl. H01L 21/67; H01L 21/687; H01L 21/677

(52) U.S. Cl. CPC H01L 21/67167; H01L 21/68742; H01L 21/68785; H01L 21/67745; H01L 21/67754; H01L 21/67742; H01L 21/67706

(57) ABSTRACT

The invention discloses a semiconductor multi-station processing chamber. Each of the multiple station includes a downward concave accommodation defined by walls and receives a pedestal therein. The pedestal and the walls define a first gap. A showerhead plate mounted on an upper lid above the pedestal to define a processing region. A second gap for supply swiping gas is defined between the showerhead plate and the upper lid. An isolation member is liftable between the downward concave accommodation and the showerhead plate to optionally encircle a processing region defined by the pedestal and the showerhead plate or to retract back into the downward concave accommodation. Such that, when the isolation member surrounds and encircles the processing region, the station is able to be structurally isolated from its neighboring one station.

### CROSS-REFERENCE TO RELATED PATENT APPLICATION

This non-provisional application claims priority to and the benefit of, pursuant to 35 U.S.C. § 119(a), patent application Serial No. CN201811581220.2 filed in China on Dec. 24, 2018. The disclosure of the above application is incorporated herein in its entirety by reference.

### BACKGROUND OF THE INVENTION

### Field of the Invention

The present invention discloses a semiconductor processing chamber, particularly a processing chamber having multiple isolated stations and means for transferring wafers among the stations.

### Description of the Prior Art

Production capacity is always a challenge in semiconductor manufacture. With technology progress, semiconductor substrates need to be processed successively and efficiently. For example, multi-chamber manufacturing equipment and cluster tools can satisfy such need, which can process batches of substrates without altering the primary vacuum condition in some certain substrate processes of the entire process flow. Such multi-chamber equipment replaces the flow that merely deals with one single substrate in which the substrate may be transferred to another chamber and be exposed to another pressure. A processed substrate in a processing chamber can be transferred to another processing chamber under the same vacuum condition for next process by connecting multiple processing chambers to a common transfer chamber.

An issued U.S. Pat. No. 6,319,553, discloses a multi-station processing chamber capable of performing incompatible processes simultaneously. The chamber includes a base having plural downward concave accommodations in which pedestals for supporting wafers or substrates are received. A gap is formed between a wall defining the accommodation and the pedestal. The chamber also includes plural showerheads arranged above and aligned with the pedestals so that a showerhead supplies reaction gases onto the substrate or wafer on the pedestal. The reaction gas is pulled down to the downward concave accommodation through the gap and pumped out by an exhaust system. The chamber further includes an indexing plate for transferring a substrate or a wafer from one station of the chamber to another station of the chamber. Stations of the chamber can be mutually isolated, by an airflow means, in order to perform the incompatible processes respectively at the same time. Since different processes can be performed at a same time, the idle period of a station can be reduced, and whereby increasing the productivity.

Nevertheless, other equipment similar to the foregoing multi-station processing chamber may exist some drawbacks. For example, substrates or wafers may be contaminated during the transfer from station to station, and these stations may interfere with each other in the environment where plasma process or heating process takes place, which could influence the product yield and productivity.

Therefore, there is a demand in the industry to contain the contamination during the processing flow while enhance the isolation among the stations of the multi-station processing chamber.

### SUMMARY OF THE INVENTION

One objective of the present invention is to provide a semiconductor multi-station processing chamber, having multiple stations communicating with each other and configured to perform one or more processes. Each of the stations includes a downward concave accommodation defined by plural walls and receiving a pedestal for supporting a substrate or a wafer, wherein the pedestal and the walls defining the downward concave accommodation form a first gap therebetween; a covering assembly mounted to an upper lid above the pedestal to define a processing region, the covering assembly including a showerhead plate, and a second gap being formed between the showerhead plate and the upper lid; and an isolating member liftable in a space between the downward concave accommodation and the covering assembly in order to optionally encircle the processing region defined by the pedestal and the covering assembly or retractable back into the downward concave accommodation, and when the isolating member encircles the processing region, the station is structurally isolated from another neighboring station.

In a preferred embodiment, the stations communicate with each other via a transferring layer, and the transferring layer allows one or more arms of said chamber pass through the stations. In a preferred embodiment, said arm has a first extension and a second extension connecting to the first extension, the connection of the first extension and the second extension is configured to have an angle that allows the arm to stay in a stay space defined between two neighboring isolated stations.

In a preferred embodiment, each of the stations further includes a perforated cover securely received in the downward concave accommodation to define a exhaust chamber therein, and the perforated cover has plural through holes via which the processing region communicates with the exhaust chamber.

In a preferred embodiment, the first gap, the second gap and the through holes determine an exhaust path of the station.

Another objective of the invention is to provide a semiconductor processing system including a semiconductor multi-station processing chamber having multiple stations communicating with each other and configured to perform one or more processes; a load lock chamber configured to load processed or unprocessed substrates or wafers; and a transfer chamber connecting the semiconductor multi-station processing chamber and the load lock chamber to deliver the substrates or wafers. Each of the stations includes: a downward concave accommodation defined by plural walls and receiving a pedestal for supporting a substrate or a wafer, wherein the pedestal and the walls defining the downward concave accommodation form a first gap therebetween; a covering assembly mounted to an upper lid above the pedestal to define a processing region, the covering assembly including a showerhead plate, and a second gap being formed between the showerhead plate and the upper lid; and an isolating member liftable in a space between the downward concave accommodation and the covering assembly in order to optionally encircle the processing region defined by the pedestal and the covering assembly or retractable into the downward concave accommodation, and when the isolating member encircles the processing region, the station is structurally isolated from another neighboring station. In a preferred embodiment, the load lock chamber has plural vertical stacked layers for storing substrates or wafers, and the load lock chamber is further provided with preheating and cooling mechanism.

In a preferred embodiment, the load lock chamber has an upper chamber and a lower chamber, wherein the upper chamber is configured for storing the processed substrates or wafers while the lower chamber is configured for storing substrates or wafers to be processed.

In a preferred embodiment, the transfer chamber further couple to another transfer chamber by a buffer chamber that provides preheating and cooling mechanism.

Yet another objective of the invention is to provide a method for operating a semiconductor multi-station processing chamber having multiple stations communicating with each other. The stations are separated and concentric with respect to a center of said chamber, said chamber further including multiple arms radially arranged with respect to the center and configured to rotate to pass through the stations. The method includes moving the arms to a first waiting position and receiving a first pair of substrates by a first pair of stations of said chamber; moving the arms to a first pickup position to transfer the first pair of substrates from the first pair of stations onto the corresponding arms; moving the arms to a second waiting position and receiving a second pair of substrates by the first pair of stations; moving the arms to a second pickup position to transfer the second pair of substrates from the first pair of stations onto the corresponding arms; moving the arms to a third waiting position and receiving a third pair of substrates by the first pair of stations; moving the arms to a third pickup position to transfer the first pair of substrates and the second pair of substrates from the arms onto a second pair of stations and a third pair of stations respectively; and moving the arms to a fourth waiting position until processes performed by said chamber end.

In a preferred embodiment, the first waiting position, the second waiting position and the third waiting position are different from each other while the first pickup position, the second pickup position and the third pickup position are different from each other.

In a preferred embodiment, receiving the first pair of substrates by the first pair of stations of said chamber, including supporting the first pair of substrates by plural lift pins of the first pair of stations.

In a preferred embodiment, to transfer the first pair of substrates from the first pair of stations onto the corresponding arms, including transfer the first pair of substrates from the lift pins onto the corresponding arms.

In a preferred embodiment, the number of stations is a multiple of two.

A further objective of the invention is to provide a method for operating a semiconductor multi-station processing chamber having multiple stations communicating with each other. The stations are separated and concentric with respect to a center of said chamber, said chamber further includes multiple arms radially arranged with respect to the center and configured to rotate to pass through the stations. The method includes: moving the arms to a first waiting position to retrieve a first pair of substrates from a first pair of stations of said chamber; moving the arms to a first pickup position to transfer a second pair of substrates from a second pair of stations onto the corresponding arms; moving the arms to a second pickup position to transfer the second pair of substrates onto the first pair of stations; and moving the arms to a second waiting position to retrieve the second pair of substrates from the first pair of stations.

In a preferred embodiment, the first waiting position and the second position are different from each other while the first pickup position and the second position are different from each other. In a preferred embodiment, to retrieve the first pair of substrates from the first pair of stations, including transfer the first pair of substrates from plural lift pins onto a machine arm. In a preferred embodiment, to transfer the second pair of substrates from the second pair of stations onto the corresponding arms, including transfer the second pair of substrates from plural lift pins of the second pair of stations onto the corresponding arms.

Yet another objective of the invention is to provide a method for operating a semiconductor multi-station processing chamber having multiple stations communicating with each other. The stations are separated and concentric with respect to a center of said chamber, said chamber further includes an arm configured to rotate with respect to the center to pass through the stations. The method includes: moving the arm among a pickup position and the stations in order to successively load or unload substrates into or from the stations, and interchanging a part of the substrates among the stations based on a process requirement, wherein the arm does not pass through the top of any substrate in the chamber.

In a preferred embodiment, one of the stations is a buffer station.

In a preferred embodiment, the number of the stations is more than two.

In a preferred embodiment, the method further comprising: moving the arm between different stations to load or unload the substrates.

One more objective of the invention is to provide an isolating member used in a station of a semiconductor multi-station processing chamber to structurally isolate the station from others, wherein the station includes a downward concave accommodation defined by plural walls and a covering assembly, the downward concave accommodation receives a pedestal for supporting substrates. The isolating member is configured to lift between the downward concave accommodation and the covering assembly to optionally encircling a processing region defined by the pedestal and the covering assembly or to retract back into the downward concave accommodation.

In a preferred embodiment, the isolating member is a ring.

In a preferred embodiment, the isolating member is configured to lift in a gap defined between the pedestal and the walls.

In a preferred embodiment, the isolating member is configured to engage with the covering assembly.

### BRIEF DESCRIPTION OF THE DRAWINGS

The foregoing invention and other features and advantages will be more understood with reference to the following described embodiments and drawings.

FIG. 1 illustrates an embodiment of the semiconductor multi-station processing chamber (without an upper lid and a rotating assembly) according to the present invention.

FIG. 2 is a bottom view of the upper lid of the semiconductor multi-station processing chamber according to the present invention.

FIG. 3 is a top view of a main body (with the rotating assembly and arms) of the semiconductor multi-station processing chamber according to the present invention.

FIG. 4 shows an enlarged view of a portion of the rotating assembly and the arms in FIG. 3.

FIG. 5 is a cross-sectional view of the semiconductor multi-station processing chamber according to the present invention, including the upper lid and the main body.

FIG. 6 is a cross-sectional view of one station (not isolated) of the semiconductor multi-station processing chamber according to the present invention.

FIG. 7 is a cross-sectional view of one station (structurally isolated) of the semiconductor multi-station processing chamber according to the present invention.

FIGS. 8A to 81 exemplify substrate loading motions of the semiconductor multi-station processing chamber according to the present invention.

FIG. 9 illustrates a loading operation block diagram performed by the semiconductor multi-station processing chamber according to the present invention.

FIGS. 10A to 10H exemplify substrate unloading motions of the semiconductor multi-station processing chamber according to the present invention.

FIG. 11 illustrates an unloading operation block diagram performed by the semiconductor multi-station processing chamber according to the present invention.

FIGS. 12A to 12C exemplify an operation performed by the semiconductor multi-station processing chamber according to the present invention.

FIGS. 13A to 13B exemplify another operation performed by the semiconductor multi-station processing chamber according to the present invention.

FIGS. 14A to 14B respectively exemplify a semiconductor processing system including the semiconductor multi-station processing chamber according to the present invention.

### DETAILED DESCRIPTION OF THE PREFERRED EMBODIMENTS

The following description will explain the present invention more fully with reference to the appended drawings, and will show certain embodiments by way of examples. However, the subject matter of the present invention may be embodied in various forms, and the present invention shall not be limited by any exemplary embodiments disclosed herein. The embodiments described herein are for exemplary purposes only. Similarly, the present invention shall be construed in a reasonably broad manner. In addition, as the subject matter of the present invention may be embodied as a method, device or system, the embodiments described herein may include examples in the form of hardware, software, firmware or any combination thereof (but excluding software-only scenarios).

The phrase “in one embodiment” as used herein does not necessarily refer to the same embodiment being described. Similarly, the phrase “in another embodiment” does not necessarily refer to a different embodiment from the one being described. The claimed subject matter may include all the elements described in an exemplary embodiment, or a combination of part of the elements described in an exemplary embodiment.

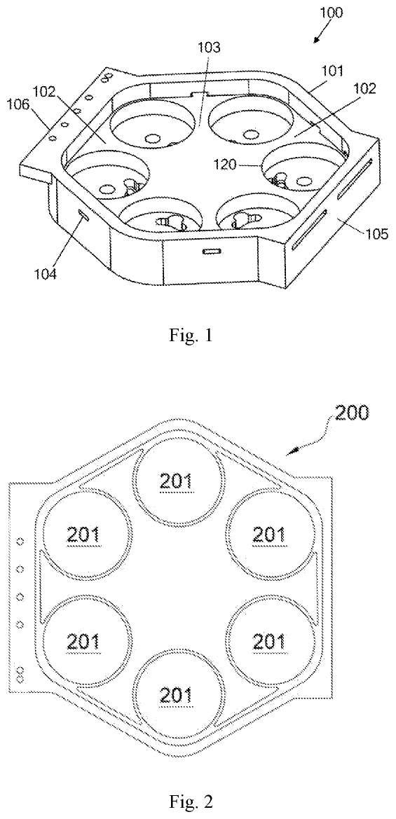

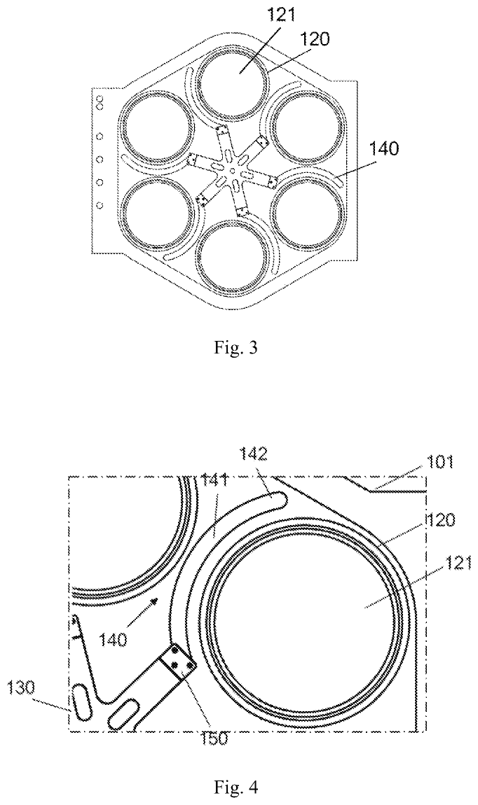

A multi-station processing chamber for semiconductor according to the present invention includes a main body and an upper lid covering the main body to form multiple processing stations. FIG. 1 shows an embodiment (100) a main body of the semiconductor multi-station processing chamber according to the invention without presenting an upper lid, a pedestal and rotating assembly. FIG. 2 shows a bottom view of an upper lid (200) of the semiconductor multi-station processing chamber according to the invention. FIG. 3 shows a top view of the main body of the semiconductor multi-station processing chamber, which includes plural pedestals, a rotating assembly and plural arms.

The main body (100) of said chamber has an outer wall (101) defined by a polygon, plural inner walls (102), a center wall (103) and a bottom (not shown). In the illustrated embodiment, the outer wall (101) is the outer wall defined by a hexagon and may provide observation windows (104) that allows the observer outside of the chamber to see the chamber interior. The outer wall (101) and the bottom (not shown) define a main space within said chamber that is sufficient for arranging multiple stations providing certain processes. The outer wall (101) provides a pair of loading and unloading ports (105) at its one side for loading the substrates and wafers to be processed and unloading the processed ones. The outer wall (101) further provides a gas supplying assembly (106) at its one side that extends laterally and is provided with many restricting structures, such as holes, in order to allow longitudinal penetration of various pipes dispensing reaction gases and purge gases (or isolation gas) to a covering assembly of the upper lid (200). Alternatively, in other embodiment, said outer wall may be defined by more polygons other than hexagon, or said outer wall may be circular or rectangular.

The inner wall (102) longitudinally extends from the bottom and laterally extends between the outer wall (101) and the center wall (103), wherein the center wall (103) is located at the center of the main body (100). Whereby, the outer wall (101), the inner walls (102) and the center wall (103) define multiple downward concave accommodations (120). Each of the downward concave accommodations (120) corresponds to and is adjacent to the corners of the hexagon outer wall such that the downward concave accommodations are properly separated. Despite not shown in FIG. 1, these downward concave accommodations (120) are provided therein with pedestals for supporting substrates, and the bottom of these downward concave accommodations (120) are further provided with an exhaust channel for fluidly coupling to the exhaust system.

The upper lid (200) covers the top of the main body (100) with multiple covering assemblies (201) aligning with the downward concave accommodations (120). The covering assembly (201) is provided at the inner side of the upper lid (200), i.e. the top of the main body (100). The upper lid (200) may be structured in a way corresponding to the main body (100), such as a similar outer wall and gas supply assembly. A single downward concave accommodation, a single pedestal and a single covering assembly establishes a single processing station. As shown in the configuration said chamber has six stations which can perform different processes. Wherein, a pair of neighboring stations is arranged to face a pair of valve gates of said loading and unloading ports (105) to receive and off load substrates.

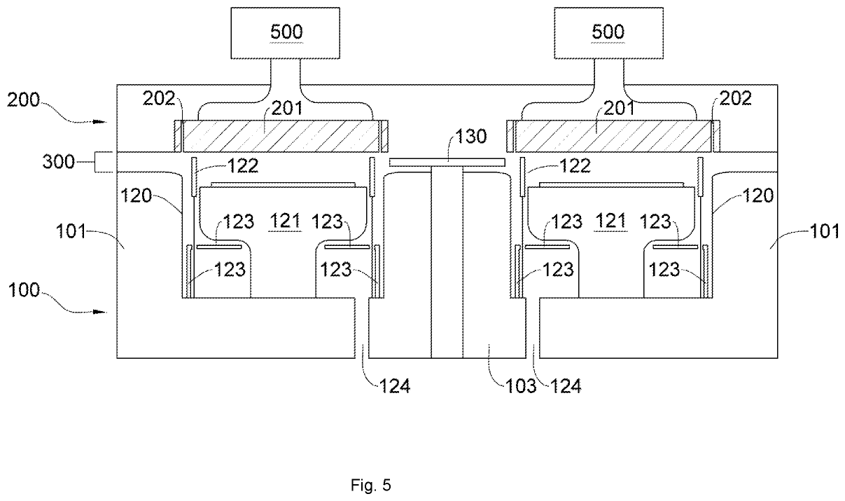

The covering assembly (201) is configured to supply reaction gases onto the supported substrate. Each covering assembly is structurally complicated, and for example, may include a gas mixing area, a mounting plate, an isolator, a gas distributor assembly and a showerhead plate. Wherein, the showerhead plate has many holes for supplying the reaction gas, and may be served as an RF reaction plate for plasma generation. Said showerhead plate is centrally aligned with the pedestal, and generally the diameter of the showerhead plate is slightly larger than that of the pedestal. In addition, the covering assembly (201) can be configured to supply the pure gas or isolation gas to guarantee the station isolation. Each covering assembly (201) fluidly couples to one or more gas supply sources as shown in FIG. 5. For brevity purpose, the covering assemblies (201) of the paired station may share a common gas supply source. One gas supply source can send reaction gas to the two of the covering assemblies (201) via manifold. The gas supply source may further include a heater and flow rate controller which are known by the person skilled in the art, and therefore their details are neglected. Said covering assembly (201) may be configure to adapt processes like PECVD, 3D-NAND PECVD, atomic layer deposition, PVD or other chemical vapor deposition processes.

FIG. 3 shows the main body (100) of said chamber, including multiple pedestals (121) disposed in the downward concave accommodations (120), a rotating assembly (130) and multiple arms (140) connected to the rotating assembly (130). Each of the pedestals (121) is independently adjustable and has a carrying surface for carrying a wafer or substrate. The material of the pedestal (121) is basically metal or ceramic. The pedestal (121) includes a heater that can be embedded in the pedestal (121) or separated therefrom. In addition, the pedestal (121) can be configured as a lower electrode for plasma generation. In other possible embodiments, in addition to that where the pedestal (121) has heating ability, the pedestal (121) may be further configured to have the ability to cool down the wafer or maintain its temperature. The rotating assembly (130) is positioned at the center of said chamber. The embodiment as shown in figure, the rotating assembly (130) is a radial indexing plate that can rotate in a clockwise or counterclockwise relatively to said chamber by an axle and a driver (not shown) coupled thereto. The rotating assembly (130) has multiple radial extensions that couple to the arms (140) made of thermal resistant material via a respect connector (150). As shown in the embodiment, the rotating assembly (130) has six extensions. In other embodiments, the rotating assembly (130) has more or less extensions. The extension of the rotating assembly (130) is configured to connect with the connector (150). The connector (150) provides optional connections so that the connector (150) connects with the arm (140). In one embodiment, said optional connections are carried out by detachable bolts to whereby adjust the radial position of the arms (140) relative to the center of said chamber or adjust an elevation angel and orientation of the arm (140). The material of the arm (140) can be ceramic (Al₂O₃) or others having similar or less coefficient of thermal expansion. In one embodiment, the vertical motion of the rotating assembly (130) is restricted so that the arms are held at a height in the chamber and rotate about the center of said chamber, and whereby the arms (140) can pass through spaces above the pedestals holding substrates. In other embodiments, more or less arms (140) may be provided in said chamber. Preferably, the number of arms (140) is a multiple of two.

FIG. 4 shows an enlarged schematic view of one arm (140). Generally, the arm (140) is shaped in flat and has a first extension (141) and a second extension (142) connecting with the first extension (141). The first extension (141) connects with the connector (150), and the second extension (142) is more close to the outer wall (101). The connection of the first extension (141) and the second extension (142) defines an angle that can be determined so that the arm (140) is allowed to stay in a stay space defined between two adjacent downward concave accommodations (120). Said angle is less than ninety degrees or can be other options, and therefore forming a “C” shape like arm. Preferably, the first extension (141) of the arm (140) may have a curved structure to match a periphery of the downward concave space (120).

FIG. 5 is a cross sectional view of said chamber, showing two paired stations in symmetric about the center of the said chamber. Said station includes a pedestal (121) disposed in the downward concave accommodation (120), a covering assembly (201) mounted to the upper lid (200) and a gas supply source (500) coupled to the covering assembly (201). The gas supply source (500) supplies a variety of gases essential for processes, such as reaction gas, purge gas and inert gas. In one embodiment, said gas supply source (500) may contain a plasma generation source. In some embodiments, two neighboring stations are configured to share a common gas supply source to reduce the equipment volume occupation. There is a transferring layer (300) between the upper lid (200) and the main body (100), and the stations communicate with each other through the transferring layer (300), allowing substrates being transferred between the stations. The rotating assembly (130) is presented in the transferring layer (300) while the pedestal (121) sits below the transferring layer (300) such that the arms (not shown here) connected by the rotating assembly (130) can pass through multiple stations within the transferring layer (300). Generally, said arms, via rotation, will move between several waiting positions and pickup positions within the transferring layer (300).

The covering assembly (201) is mounted at the inside of the upper lid (200) of the chamber. The covering assembly (201) and the pedestal (121) define a processing region of the station. The covering assembly (201) can be configured as an RF electrode for plasma treatment. In one embodiment, the covering assembly (201) may include a showerhead plate that supplies a reaction gas and a ring gap (202, a second gap) formed on at the periphery of the showerhead plate to supply a purge gas. The scale of the ring gap is about 1 mm. The diameter of the ring gap (202) is equal or slightly larger than that of the downward concave accommodation (120) so that the purge gas is able to isolate the processing region and retain the reaction gas in the station. In another embodiment, another ring gap (not shown) may be defined between the covering assembly (201) and the upper lid (200) for supplying the purge gas so that the flow of the purge gas can extend to a chamber dead zone, i.e. a zone between stations with no process being performed. In some possible embodiments, purge gas generation may be a result of a combination of the foregoing examples. In general, the purge gas is an inert gas, such as Argon. The purge gas supplied from the ring gap adjacent to the covering assembly (201) is benefit for avoiding reaction gas leakage from one processing region to one another along the transferring layer (300).

The station yet includes one or more isolating members. The isolating member is used for encircling the processing region between the covering assembly (201) and the pedestal (121) so that the chamber stations are structurally isolated. As shown in FIG. 5, there is a ring gap (a first gap, unlabeled) defined between the downward concave accommodation (120) and the pedestal (121) in each station, and the isolating member (122) can be lifted within the gap between the downward concave accommodation (120) and the pedestal (121). A chamber operation controller controls the isolating member (122). The isolating member (122) includes a ring wall that has a height sufficient to shield a side of the processing region. The ring wall optionally shields the processing region defined between the pedestal and the covering assembly by lifting means, or can retract back into the downward concave accommodation. When the isolating member encircles the processing region, a structural isolation is formed between the station and its neighboring stations. During the time of processing, the ring wall is lifted from the downward concave accommodation (120) meanwhile the rotating assembly (130) moves said arms to a corresponding waiting position. The isolating member encircling the processing region as discussed herein means that the isolating member is able to partially or fully encircle the processing region to produce a certain extent of structural isolation for each station.

During substrate transfer, the ring wall is dropped and retracted back into the downward concave accommodation (120), allowing said arms comes into and out of the processing regions for transferring substrates. In one embodiment, a ring liner (not shown) may be properly provided on the inner surface defining the downward concave accommodation (120) so that the lifted ring wall with the ring liner can prevent the reaction gas leakage from the downside of the ring wall. In another embodiment, one or more additional ring members (not shown) may be properly provided and positioned between the covering assembly (201) and the upper lid (200) so that the lifted ring wall can engage with said ring member to more prevent reaction gas leakage from the upside of the ring wall. The material of said ring wall, liner and ring member are selected from one of thermal resistant materials, such as ceramic, PEEK or PTFE, and preferably their structural thickness is not less than 4 mm.

At the bottom of the downward concave accommodation further, a perforated cover (123) is provided and may be composed by one or more members. The perforated cover (123), an outer surface of the pedestal (121) and the bottom of the downward concave accommodation (120) define an exhaust chamber. The exhaust chamber further fluidly communicates with an exhaust channel (124) below the downward concave accommodation (120). The perforated cover (123) has many through holes through which the upper processing region communicates with the lower exhaust chamber. In one embodiment, the perforated cover (123) has eighteen through holes with different diameters and these through holes can be properly arranged to obtain a variety of pumping rates. For each station, the purge gas and the processing gas pass through the gap at the periphery of the pedestal (121) and then are gathered within said exhaust chamber, and finally pumped out of the chamber via the hidden exhaust channel (124). In one embodiment, each station has at least one exhaust channel. The exhaust chamber is able to keep the product after reaction, the non-reacted product and the purge gas from flowing back to the processing region and causing contamination.

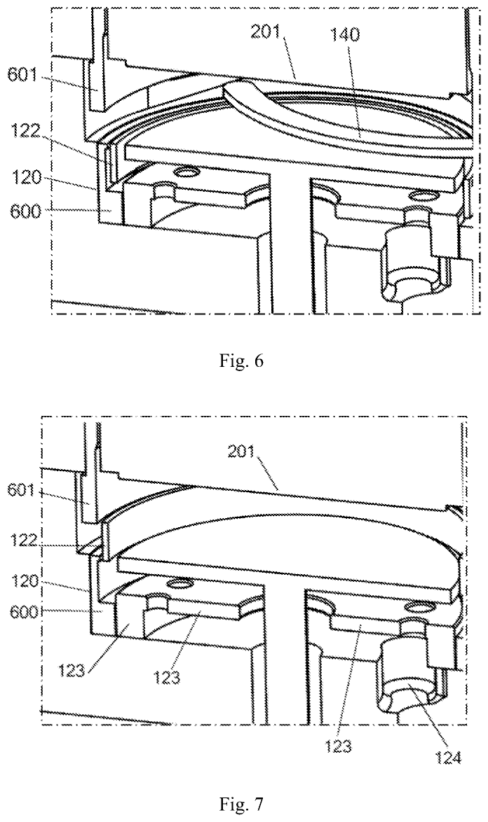

FIG. 6 shows a cross sectional view of a station in which the isolating member (122) is hidden at the position between the downward concave accommodation (120) and the pedestal (121), i.e. the station is operated in an open state that allows an arm (140) to stay above the pedestal (121). The carrying surface of the pedestal (121) may provide plural lift pins (not shown) which is able to lift a substrate from the carrying surface at a height level close to the arm (140). FIG. 6 further illustrates that the inner surface of the downward concave accommodation (120) is provided with a liner (600) facing the isolating member (122), while a ring member (601) extending downward from a periphery of the covering assembly (201) encircles an upper portion of the processing region without interfering the arm's motion. FIG. 7 shows a cross sectional view of the station in which the isolating member (122) is lifted to encircle said processing region. Despite absence in the figure, the ring wall, such as a top side of the isolating member (122) engages with the upper ring member (601) while there is still a gap between the bottom of the ring wall and the liner (600). This is to, in some particular cases, allow purge flow from a dead zone to enter the exhaust chamber below. Of course, for some designs, a bottom of the ring wall may be configured to engage with the liner (600) in order to enhance the isolation ability among stations. According to the above description, the station may have at least one exhaust path that is determined by said first gap, said second gap, said through holes and said exhaust chamber.

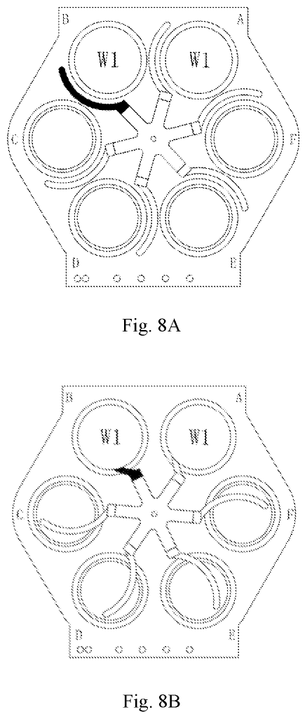

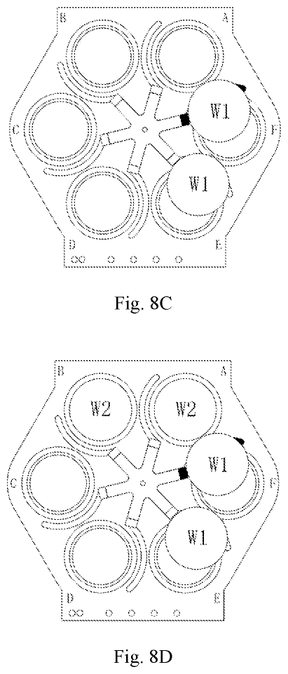

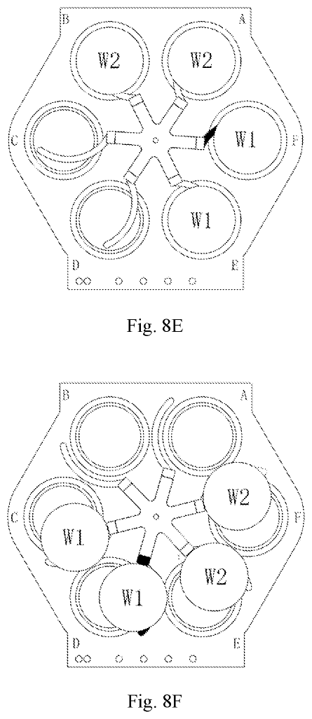

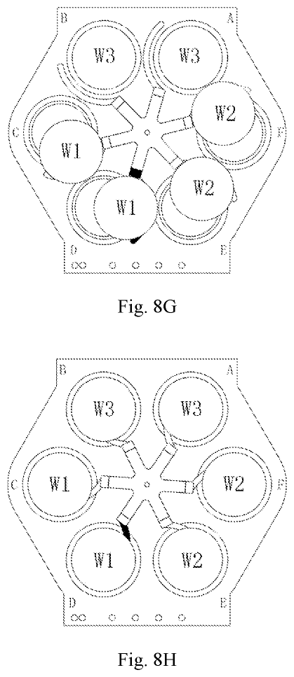

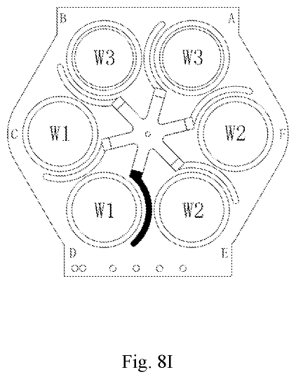

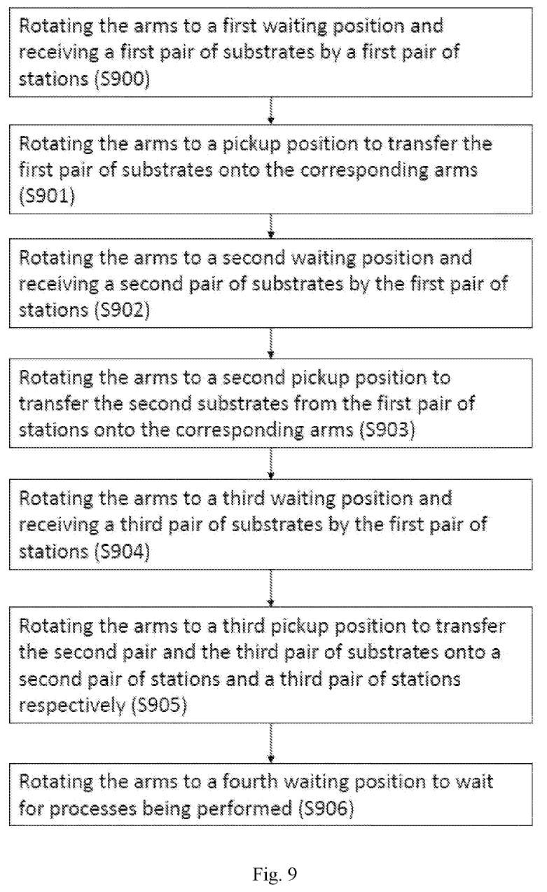

FIGS. 8A to 81 schematically show a serious of substrate loading motions of the semiconductor multi-station processing chamber according to the invention. FIG. 9 shows a flow chart for loading substrates performed by the semiconductor multi-station processing chamber according to the invention, which includes steps S900 to S906. Referring those FIGS. 8A to 81 and FIG. 9, the operation of loading substrates to multiple stations in the chamber will be described below.

At step S900, as shown in FIG. 8A, the arms are rotated and stopped at a first waiting position, and a first pair of substrates (W1) is received by a first pair of stations (A and B). To explain a serious of the arm's motions, one of these arms is filled with black color in the figures to be indicated as a first arm. Before receiving the first pair of substrates (W1), the stations communicate with each other, and each of these arms are rotated and stopped at the first waiting position among the stations. At this moment, the first arm stays at a position between stations B and C while there is no obstacle between the stations A and B and the loading/unloading ports (105). The first pair of substrates (W1) is delivered by a machine arm into the chamber and placed onto the pedestals of stations A and B. At this moment, lift pins of stations A and B are set to a high position. Step S900 ends.

At step S901, as shown in FIG. 8B, the arms are rotated and stopped at a first pickup position in order to transfer the substrate (W1) from the first stations (A and B) onto the corresponding arms. As shown in figure, the arms clockwise enter into corresponding stations. At this moment, the first arm enters into station B and stays below the substrate of station B. lift pins then move to a low position in order to transfer the first pair of substrates (W1) to the arms located at the stations A and B. Step S901 ends.

At step S902, as shown in FIGS. 8C and 8D, the arms are rotated and stopped at a second waiting position, and a second pair of substrates (W2) is received by the first pair of stations (A and B) of said chamber. Before receiving the second pair of substrates (W2), the stations communicate to each other, and each of the arms is rotated and stopped at the second waiting position among the stations. At this moment, the first arm stays at a position between station A and station F meanwhile there is no obstacle between stations A and B and the loading/unloading ports. The second pair of substrates (W2) is delivered into the chamber by the machine arm through the loading/unloading ports and placed onto the pedestals of stations A and B. At this moment, the lift pins of stations A and B are set to the high position to support the second pair of substrates (W2). Step S902 ends.

At step S903, as shown in FIG. 8E, the arms are rotated and stopped at a second pickup position in order to transfer the second pair of substrates (W2) from the first pair of stations (A and B) onto the corresponding arms. The arms clockwise enter into corresponding stations. At this moment, the first arm enters into station F while two of the arms enter into station A and station B respectively. The lift pins of stations A and B move to the low position in order to transfer the second pair of substrates (W2) onto the arms. Step S903 ends.

At step S904, as shown in FIGS. 8F and 8G, the arms are rotated and stopped at a third waiting position, and a third pair of substrates (W3) is received by the first pair of stations (A and B) of said chamber. Before receiving the third pair of substrates (W3), the stations communicate to each other, and each of these arms is rotated and stopped at the third waiting position among the stations. At this moment, the first arm stays at a position between station D and station E meanwhile there is no obstacle between station A and station B and the loading/unloading ports. The third pair of substrates (W3) is delivered into the chamber by the machine arm through the loading/unloading ports and placed onto the pedestals of stations A and B. At this moment, the lift pins of station A and station B are set to the high position to support the third pair of substrates (W3). Step S904 ends.

At step S905, as shown in FIG. 8H, the arms are rotated and stopped a third pickup position in order to transfer the first pair of substrates (W1) onto a second pair of stations (C and D) and transfer the second pair of substrates (W2) onto a third pair of stations (E and F). The arms clockwise enter into the corresponding stations. At this moment, the first arm enters into station D while other arms enter into corresponding stations. Lift pins of station C to station F are set to the high position in order to respectively transfer the first pair of substrates (W1) and the second pair of substrates (W2) onto the pedestals of station C to station F. At this moment, these substrates are separated away from the arms. Step S905 ends.

At step S906, as shown in FIG. 8I, the arms are rotated and stopped at a fourth waiting position to wait for processes performed in the chamber until completed. The arms are rotated and stopped at the fourth waiting position among the stations. At this moment, the first arm returns to an initial position (e.g. a position that the indexing plate is set to an original value). Said initial position may be different from or close to the fourth waiting position. As shown in figure, the first arm is counterclockwise rotated and stopped at a position between station D and station E. the lift pins of station A to station F move to the low position so that these substrates (W1, W2 and W3) drop to a processing level above the pedestals. Afterward, the ring walls of the stations are lifted so that these stations are structural isolated. Step S906 ends.

In some possible embodiments, one or more processing steps may be interspersed among the foregoing steps in the case where chamber is not fully loaded. Said first waiting position, second waiting position and third waiting position of the arms are different, and said first pickup position, second pickup position and third pickup position are different as well. In one embodiment, the number of stations in a chamber does not have to be only six, the number may be a multiple of two. In addition, said waiting position and said pickup position do not have to refer to a physical mounting position. That is, among different batches of processing, said waiting position and said pickup position described herein may indicate different physical positions. The figures merely depict one single batch of processing according to certain embodiment, and its successive batches of processing may be similar but do not have to exactly the same scheme of the arm's motions.

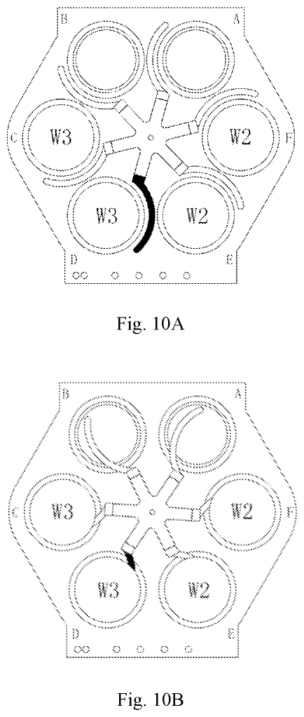

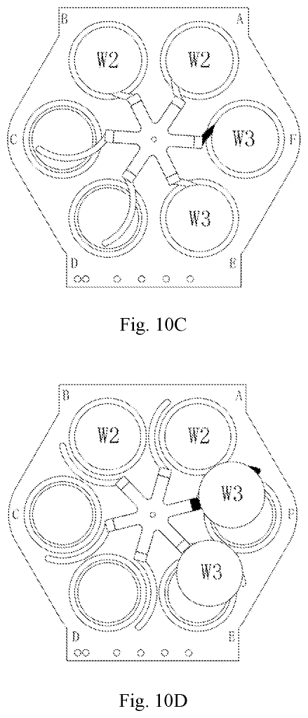

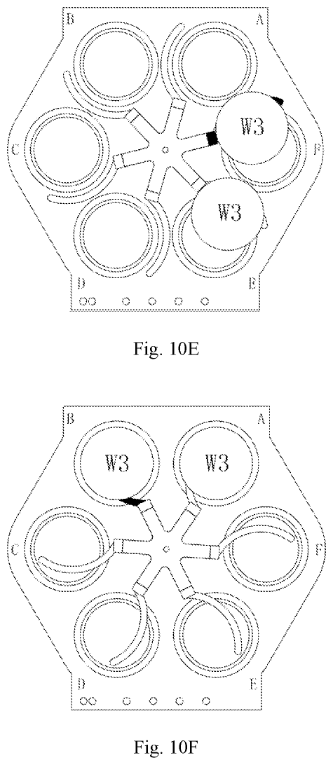

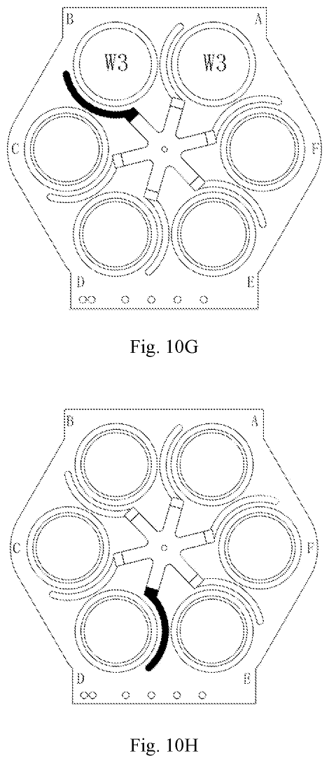

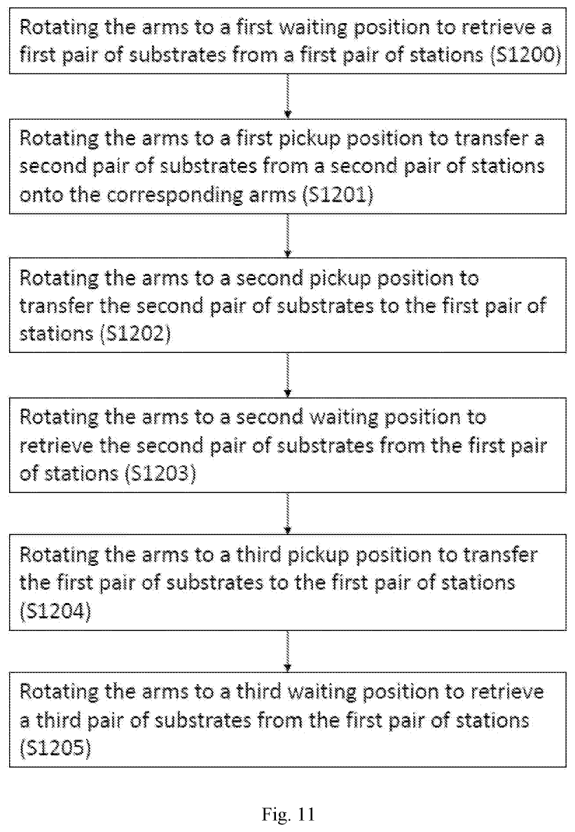

FIGS. 10A to 10H schematically show a serious of substrate unloading motions of the semiconductor multi-station processing chamber according to the invention. FIG. 11 shows a flow chart for unloading substrates performed by the semiconductor multi-station processing chamber according to the invention, which includes steps S1200 to S1206. Referring those FIGS. 10A to 10H and FIG. 11, the operation of unloading substrates from multiple stations in the chamber will be described below.

At step S1200, as shown in FIG. 10A, the arms are rotated and stopped at a first waiting position (which is different from the foregoing first waiting position) in order to retrieve a first pair of substrates (not shown) from a first pair of stations (A and B). The station ring walls are dropped after processes finish so that the stations communicate to each other. At this moment, the arms can be stopped at the first waiting position, wherein the first arm stays at a position between station D and station E so that there is no obstacle between stations A and B and the loading/unloading ports. The first pair of substrates supported by the lift pins of the high position on stations A and B is retrieved out of the chamber by a machine arm through the loading/unloading ports.

At step S1201, as shown in FIG. 10, the arms are rotated and stopped at a first pickup position (which is different from the foregoing first pickup position) in order to transfer a second pair of substrates (W2) onto the corresponding arms from a second pair of stations (E and F). The arms clockwise enter into the station E and station F below the substrates (W2). At this moment, the first arm stays in station D below a substrate (W3). The lift pins of station C to station F move to the low position so that the second pair of substrates (W2) and the third pair of substrates (W3) are transferred onto the corresponding arms. Step S1201 ends.

At step S1202, as shown FIG. 10C, the arms are rotated and stopped at a second pickup position (which is different from the foregoing second pickup position) in order to transfer the second pair of substrates (W2) to the first pair of stations (A and B). The arms are counterclockwise rotated. At this moment, the first arm stays in station F while the second pair of substrates (W2) locate in station A and station B. The lift pins of station A and station B are lifted to the high position in order to transfer the second substrates (W2) from the arms onto the pedestals of station A and station B while the third pair of substrates (W3) is supported by the arms. Step S1202 ends.

At step S1203, as shown in FIGS. 10D to 10E, the arms are rotated and stopped at a second waiting position (which is different from the foregoing second waiting position) in order to retrieve the second pair of substrates (W2) from the first pair of stations (A and B) out of said chamber. The arms leave the second waiting position between the stations. At this moment, the first arm stays in a position between station A and station F so that there is no obstacle between station A and station B and the loading/unloading ports. The second pair of substrates (W2) are retrieved from the chamber through the loading/unloading ports by the machine arm. Step S1203 ends.

At step S1204, as shown in FIG. 10, the arms are rotated and stopped at a third pickup position (which is different from the foregoing third pickup position) in order to transfer the third pair of substrates (W3) to the first pair of stations (A and B). The arms counterclockwise enter into the corresponding stations. At this moment, the first arm stays in station B while the third pair of substrates (W3) stays in station A and station B respectively. The lift pins of station A and station B are lifted to the high position in order to transfer the third pair of substrates (W3) from the arms onto the pedestals of station A and station B. Step S1204 ends.

At step S1205, as shown in FIGS. 10G and 10H, the arms are rotated and stopped at a third waiting position (which is different from the foregoing first pickup position) in order to retrieve third pair of substrates (W3) from the first pair of stations (A and B) out of the chamber. The arms counterclockwise leave stations and stay at the third waiting position among the stations. At this moment, the first arm stays at a position between station B and station C so that there is no obstacle between stations A and B and the loading/unloading ports. The third pair of substrates (W3) is retrieved from the chamber through the loading/unloading ports. Step S1205 ends.

In some possible embodiments, one or more processing steps may be interspersed among the foregoing steps in the case where the chamber is unnecessary fully loaded. In other possible embodiments, a portion of steps S900 to S906 and a portion steps S1205 to S1205 may be rearranged or combined with each other so that said substrate loading, processing and unloading can be successively performed in a serious of programs.

The above described embodiments explain the process for delivering substrates with multiple arms. However, in other possible embodiments, the chamber according to the invention may use single arm to complete the substrate loading and offloading. Considering the single arm case where the arm can be moved between a pickup position and multiple stations in order to one-by-one load or unload multiple substrates to or from the stations, wherein the arm does not pass through the top of any substrate during its movement. Referring to FIG. 8 or FIG. 10, for an example, the arm at a pickup position (in station A or B) can receive a substrate loaded from outside of the chamber and places it in an innermost station (e.g. station D or E), and then places others in the middle stations (e.g. stations C and F) and finally in the outermost stations (e.g. stations A and B). In other words, the single arm fill the innermost stations at first and then the outer portion while the process of unloading may be opposite. Furthermore, during the movement the arm does not pass through the top of any substrate in order to keep substrate surface from contaminated. In possible operations, one of the stations may be idle and served as a buffer station, such as station A or station B close to the outside. A substrate in the buffer does not undergo any process. For the single arm configuration, station number of the chamber may be more than two.

Based on said chamber transfer mechanism, the chamber according to the invention is able to perform a loop coating process that attains expected coating thickness as desired by loop accumulation of single coatings. These coatings may be identical or different coatings. In some embodiments, substrates in two, three or four stations of symmetric arrangement can interchange, and therefore an interchanged substrate can be processed by another covering assembly and the coating thickness can be compensated as well, improving thickness uniformity on the substrates. The examples will be described in the follows.

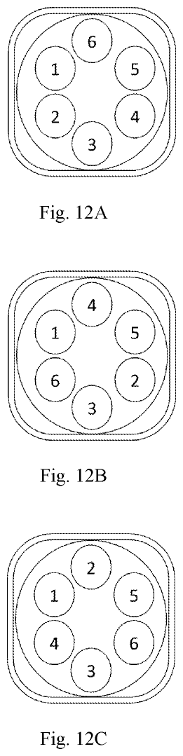

FIGS. 12A to 12C schematically show an operation of the semiconductor multi-station processing chamber according to the invention. The chamber has six stations respectively loaded with substrates (1, 2, 3, 4, 5, 6 ordered in a counterclockwise). A fully loaded chamber according to the invention may interchange the substrates between stations without opening the chamber. As shown in the figure, a first substrate (1), a third substrate (3) and a fifth substrate (5) stay in respective stations while a second substrate (2), a fourth substrate (4) and a sixth substrate (6) are transferred counterclockwise to other stations. In the process, lift pins that supporting the first substrate (1), the third substrate (3) and the fifth substrate (5) are set to a low position, while lift pins supporting the second substrate (2), the fourth substrate (4) and the sixth substrate (6) move between a high position and a low position to complete the transfer between the arms and stations. In some possible embodiments, the chamber according to FIG. 12A performs a first process, the chamber according to FIG. 12B performs a second process and the chamber according to FIG. 12C performs a third process. These stations can be performed simultaneously in all or part of the stations, and these stations can perform identical or various processes with more loops.

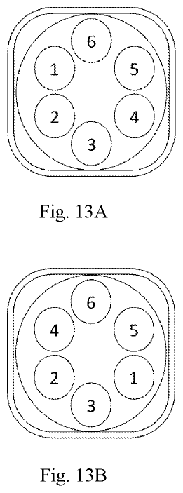

FIGS. 13A to 13B schematically show another operation of the semiconductor multi-station processing chamber according to the invention. Similarly, the chamber is fully loaded with multiple substrates (1, 2, 3, 4, 5 and 6 ordered in counterclockwise), wherein a first substrate (1) is interchanged with a fourth substrate (4) during one time transferring while other substrates stays in their respective stations.

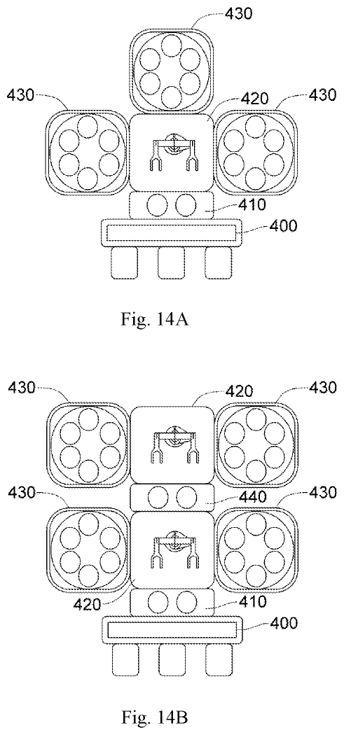

FIG. 14A schematically show an arrangement of a semiconductor processing system according to the invention, including an equipment front end module (400, EFEM), a load lock chamber (410), a transfer chamber (420) and three multi-station processing chambers (430). FIG. 14B schematically show another arrangement of a semiconductor processing system according to the invention, including double transfer chambers (420) interconnected a buffer chamber (440). EFEM (400) includes a machine arm and elevating mechanism responsible for loading and unloading substrates or wafers in the system. The substrates loaded from plural ports will be loaded into the load lock chamber (410) via the EFEM and head to the processing chambers (430). In one embodiment, the load lock chamber (410) has a vertical stack of layers for storing several substrates or wafers, and even more has preheating and cooling ability for high temperature treatment, which aids increment of productivity in the semiconductor processing system. In other embodiments, the load lock chamber has an upper chamber and a lower chamber, wherein the upper one stores substrates or wafers that have been processed and the lower one stores substrates or wafers that have not been processed. In some embodiments, the load lock chamber (410) is configured to have vertical stacked chambers in symmetrical arrangement to improve capacity of the load lock chamber. The load lock chamber further includes gas exhaust and supply system that adjusts pressure in the load lock chamber (410) to match with the transfer chamber (420). In general, the transfer chamber (420) has a pair of machine arm able to deliver at least two substrates at the same time. The buffer chamber (440) includes plural isolated layers or cavities which may be configured to perform substrate heating and cooling, increasing productivity of the semiconductor processing system.

As to the multi-station processing chamber (430), in which each station includes a downward concave accommodation defined by plural walls, a covering assembly and an isolating member. The downward concave accommodation provides a pedestal for supporting a substrate or a wafer, and the pedestal and inner walls defining the downward concave accommodation forms a first gap. The covering assembly is mounted to a lid above the pedestal to define a processing region. The covering assembly includes a showerhead plate, and a second gap for supplying a purge gas is defined between the showerhead and the lid. Alternatively, an outlet of the purge gas may be integrated into the showerhead. The isolating member can be lifted and dropped in a space between the downward concave accommodation and the covering assembly to whereby optionally encircle the processing region defined between the pedestal and covering assembly, or retracted back to the downward concave accommodation. When the isolating member encircles the processing region, the neighboring two stations form a mutually structural isolation. As shown in FIG. 14A, each of the processing chambers (430) has six stations, and the system is able to process at most eighteen substrates simultaneously and utilizes the foregoing loop process to obtain a uniform deposition thickness. In comparison, FIG. 14B merely adds one more processing chamber, but the addition of the buffer chamber (440) apparently increases substantial capacity of the system. As a whole, substrate productivity is effectively improved.

The foregoing content provides a complete description of combination and use of the described embodiments. These embodiments will exist within the following claims since more embodiments may be created without departure from the scope and spirit as described herein.

What is claimed is:

1. A semiconductor multi-station processing chamber, having multiple stations communicating with each other and configured to perform one or more processes, each of the stations comprising:
a downward concave accommodation defined by plural walls and receiving a pedestal for supporting a substrate or a wafer, wherein the pedestal and the walls defining the downward concave accommodation form a first gap therebetween;
a covering assembly mounted to an upper lid above the pedestal to define a processing region, the covering assembly including a showerhead plate, and a second gap being formed between the showerhead plate and the upper lid; and
an isolating member liftable in a space between the downward concave accommodation and the covering assembly in order to optionally encircle the processing region defined by the pedestal and the covering assembly or retractable back into the downward concave accommodation, and when the isolating member encircles the processing region, the station is structurally isolated from another neighboring station.

2. The semiconductor multi-station processing chamber as claimed in claim 1, wherein the stations communicate with each other via a transferring layer, and the transferring layer allows one or more arms of said chamber pass through the stations.

3. The semiconductor multi-station processing chamber as claimed in claim 2, wherein said arm has a first extension and a second extension connecting to the first extension, the connection of the first extension and the second extension is configured to have an angle that allows the arm to stay in a stay space defined between two neighboring isolated stations.

4. The semiconductor multi-station processing chamber as claimed in claim 1, wherein each of the stations further includes a perforated cover securely received in the downward concave accommodation to define a exhaust chamber therein, and the perforated cover has plural through holes via which the processing region communicates with the exhaust chamber.

5. The semiconductor multi-station processing chamber as claimed in claim 4, wherein the first gap, the second gap and the through holes determine an exhaust path of the station.

6. A semiconductor processing system, comprising:
a semiconductor multi-station processing chamber having multiple stations communicating with each other and configured to perform one or more processes, each of the stations comprising:
a downward concave accommodation defined by plural walls and receiving a pedestal for supporting a substrate or a wafer, wherein the pedestal and the walls defining the downward concave accommodation form a first gap therebetween;
a covering assembly mounted to an upper lid above the pedestal to define a processing region, the covering assembly including a showerhead plate, and a second gap being formed between the showerhead plate and the upper lid; and
an isolating member liftable in a space between the downward concave accommodation and the covering assembly in order to optionally encircle the processing region defined by the pedestal and the covering assembly or retractable into the downward concave accommodation, and when the isolating member encircles the processing region, the station is structurally isolated from another neighboring station;
a load lock chamber configured to load processed or unprocessed substrates or wafers; and
a transfer chamber connecting the semiconductor multi-station processing chamber and the load lock chamber to deliver the substrates or wafers.

7. The semiconductor processing system as claimed in claim 6, wherein the load lock chamber has plural vertical stacked layers for storing substrates or wafers, and the load lock chamber is further provided with preheating and cooling mechanism.

8. The semiconductor multi-station processing chamber as claimed in claim 6, wherein the load lock chamber has an upper chamber and a lower chamber, wherein the upper chamber is configured for storing the processed substrates or wafers while the lower chamber is configured for storing substrates or wafers to be processed.

9. The semiconductor multi-station processing chamber as claimed in claim 6, wherein the transfer chamber further couple to another transfer chamber by a buffer chamber that provides preheating and cooling mechanism.

10. A method for operating a semiconductor multi-station processing chamber having multiple stations communicating with each other, and the stations being separated and concentric with respect to a center of said chamber, said chamber further including multiple arms radially arranged with respect to the center and configured to rotate to pass through the stations, the method comprising:
moving the arms to a first waiting position and receiving a first pair of substrates by a first pair of stations of said chamber;
moving the arms to a first pickup position to transfer the first pair of substrates from the first pair of stations onto the corresponding arms;
moving the arms to a second waiting position and receiving a second pair of substrates by the first pair of stations;
moving the arms to a second pickup position to transfer the second pair of substrates from the first pair of stations onto the corresponding arms;
moving the arms to a third waiting position and receiving a third pair of substrates by the first pair of stations;
moving the arms to a third pickup position to transfer the first pair of substrates and the second pair of substrates from the arms onto a second pair of stations and a third pair of stations respectively; and
moving the arms to a fourth waiting position until processes performed by said chamber end.

11. The method as claimed in claim 10, wherein the first waiting position, the second waiting position and the third waiting position are different from each other while the first pickup position, the second pickup position and the third pickup position are different from each other.

12. The method as claimed in claim 10, wherein receiving the first pair of substrates by the first pair of stations of said chamber, including supporting the first pair of substrates by plural lift pins of the first pair of stations.

13. The method as claimed in claim 12, wherein to transfer the first pair of substrates from the first pair of stations onto the corresponding arms, including transfer the first pair of substrates from the lift pins onto the corresponding arms.

14. The method as claimed in claim 10, wherein the number of stations is a multiple of two.

15. A method for operating a semiconductor multi-station processing chamber having multiple stations communicating with each other, and the stations being separated and concentric with respect to a center of said chamber, said chamber further including multiple arms radially arranged with respect to the center and configured to rotate to pass through the stations, the method comprising:
moving the arms to a first waiting position to retrieve a first pair of substrates from a first pair of stations of said chamber;
moving the arms to a first pickup position to transfer a second pair of substrates from a second pair of stations onto the corresponding arms;
moving the arms to a second pickup position to transfer the second pair of substrates onto the first pair of stations; and
moving the arms to a second waiting position to retrieve the second pair of substrates from the first pair of stations.

16. The method as claimed in claim 15, wherein the first waiting position and the second position are different from each other while the first pickup position and the second position are different from each other.

17. The method as claimed in claim 15, wherein to retrieve the first pair of substrates from the first pair of stations, including transfer the first pair of substrates from plural lift pins onto a machine arm.

18. The method as claimed in claim 15, wherein to transfer the second pair of substrates from the second pair of stations onto the corresponding arms, including transfer the second pair of substrates from plural lift pins of the second pair of stations onto the corresponding arms.

19. A method for operating a semiconductor multi-station processing chamber having multiple stations communicating with each other, and the stations being separated and concentric with respect to a center of said chamber, said chamber further including an arm configured to rotate with respect to the center to pass through the stations, the method comprising:
moving the arm among a pickup position and the stations in order to successively load or unload substrates into or from the stations, and interchanging a part of the substrates among the stations based on a process requirement, wherein the arm does not pass through the top of any substrate in the chamber.

20. The method as claimed in claim 19, wherein one of the stations is a buffer station.

21. The method as claimed in claim 19, wherein the number of the stations is more than two.

22. The method as claimed in claim 19, wherein the method further comprising: moving the arm between different stations to load or unload the substrates.

23. An isolating member used in a station of a semiconductor multi-station processing chamber to structurally isolate the station from others, wherein the station includes a downward concave accommodation defined by plural walls and a covering assembly, the downward concave accommodation receives a pedestal for supporting substrates, characterized in that:
the isolating member is configured to lift between the downward concave accommodation and the covering assembly to optionally encircling a processing region defined by the pedestal and the covering assembly or to retract back into the downward concave accommodation.

24. The isolating member as claimed in claim 23, characterized in that: the isolating member is a ring.

25. The isolating member as claimed in claim 23, characterized in that: the isolating member is configured to lift in a gap defined between the pedestal and the walls.

26. The isolating member as claimed in claim 23, characterized in that: the isolating member is configured to engage with the covering assembly.
